(19) United States
(12) Patent Application Publication
(10) Pub. No.: US 2005/0260771 A1
(43) Pub. Date: Nov. 24, 2005

(54) Processing device and processing method

(76) Inventors: Mitsuaki Iwashita, Yamanashi (JP); Nobuo Konishi, Yamanashi (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/520,406

(22) PCT Filed: Jul. 1, 2003
(86) PCT No.: PCT/JP03/08352

§ 371 Date: Jan. 6, 2005

(30) Foreign Application Priority Data
Jul. 8, 2002 (JP) 2002198353

(51) Int. Cl. H01L 21/00; C23C 16/00

(52) U.S. Cl. 438/1; 118/723 R

(57) ABSTRACT

An object of the present invention is to previously subject a substrate such as a wafer to predetermined processing to prevent a hard mask or the like from peeling off during polishing processing performed later. In the present invention, a sloped part such that its film thickness becomes thinner toward an outer peripheral part and an end part of the substrate on which a film is formed is formed.

### TECHNICAL FIELD

The present invention relates to a processing apparatus and a processing method of a substrate.

### BACKGROUND ART

Manufacturing processes of a semiconductor device includes a process of forming an interlayer insulating film on a semiconductor wafer (hereinafter referred to as a wafer). This interlayer insulating film forming process is performed, for example, in an SOD (Spin on Dielectric) film forming system. In the SOD film forming system, film forming processing of applying a coating solution which is a material for an insulating film onto the wafer to form a film on the wafer, thermal processing of subjecting the wafer to physical processing and chemical processing including heating processing, and the like are performed.

Moreover, in the SOD film forming system, immediately after the aforementioned film forming processing is completed, outer peripheral film removing processing of removing an outer peripheral part of the film (hereinafter referred to as an outer peripheral film) on the wafer is performed. The outer peripheral film is originally an unnecessary portion, and the outer peripheral film removing processing is performed to prevent the outer peripheral film from later becoming a source of occurrence of particles and to expose a notch portion of the wafer. The outer peripheral film removing processing is performed by discharging a removal solution from a removal solution discharge nozzle to an outer peripheral part of the wafer which is being rotated to chemically dissolve the outer peripheral film.

On the other hand, the wafer on which the interlayer insulating film is formed in the SOD film forming system is carried, for example, to another processing unit, and upper films such as a hard mask, a metal barrier, and the like are formed in sequence on the interlayer insulating film on the wafer. Thereafter, the wafer is subjected to polishing processing for smoothing the surface of the wafer. This polishing processing is usually performed by rotating the wafer and pressing a polishing pad onto the wafer which is being rotated.

Incidentally, the film on a predetermined region from an end part of the wafer is removed in the aforementioned outer peripheral film removing processing, whereby as shown in FIG. 21, an end part of an insulating film 150 on a wafer W becomes an almost vertical surface, and at an upper end part thereof, a corner part 150a is formed. Then, when the polishing processing is performed after upper films such as a hard mask 151, a metal barrier 152, and the like are formed as described above, an intensive load is imposed on the corner part 150a by the pressure of a polishing pad 153. Due to this intensive load, the hard mask 151, the metal barrier, and the like in the vicinity of the corner part 150a peel off the insulating film 150. In particular, the adhesion between the insulating film 150 and the hard mask 151 is week, so that the peeling tends to occur.

Moreover, residues 154 of organic matters, the film, and the like remain on the surface of the outer peripheral part of the wafer from which the outer peripheral film is removed. If the hard mask 151 is formed on the surface of the outer peripheral part of the wafer in this state, the adhesion between the hard mask 151 and the surface of the wafer lowers. Therefore, when the polishing processing is performed thereafter, the hard mask 151 and the like on the surface of the outer peripheral part of the wafer peel off the wafer W.

The aforementioned peeling of the hard mask 151 and the like becomes a cause of particles, and it is undesirable. Further, the peeling of the hard mask 151 and the like at the corner part 150a causes a product deficiency of the wafer since post-processing such as exposure processing in this portion cannot be properly performed.

### DISCLOSURE OF THE INVENTION

The present invention is made in view of the aforementioned point, and its object is to provide a processing apparatus and a processing method for previously subjecting a substrate such as a wafer to predetermined processing to prevent a hard mask or the like from peeling off during polishing processing performed later.

The present invention is a processing apparatus for processing a substrate on a surface of which a film is formed, comprising a film removing member for selectively removing the film on a predetermined portion of an outer peripheral part of the substrate, the film removing member including a plasma supply part for supplying plasma of a reactive gas to the film on the predetermined portion and a suction port for sucking an atmosphere in a vicinity of the predetermined portion. Incidentally, the plasma supply part may be what jets gas which is previously converted into plasma to the film on the outer peripheral part of the substrate or may be what converts a reactive gas in the vicinity of the outer peripheral part of the substrate into plasma and supplies the plasma indirectly to the outer peripheral part of the substrate.

According to the present invention, it is possible to supply the reactive plasma to the film on the predetermined portion of the outer peripheral part of the substrate and chemically react the plasma with the film on the predetermined portion. Further, it is possible to separate the film by the chemical reaction and remove components of the separated film from the suction port. Furthermore, it is possible to form an atmospheric current by suction from the supply port and guide the plasma supplied from the plasma supply part. Accordingly, by combining the supply and the guidance of the plasma, for example, it becomes possible to bring the atmospheric current which carries the plasma into oblique contact with an end part of the film on the outer peripheral part of the substrate and form a sloped part at the end part of the film. As a result, for example, even if a polishing pad is pressed on the substrate in the aforementioned polishing processing, a load does not concentrate on the vicinity of the end part of the film, which can prevent, for example, a hard mask as an upper film from peeling off. Moreover, the film remaining on the surface of the outer peripheral part of the substrate after the aforementioned outer peripheral film removing processing can be removed. As a result, the later adhesion between the surface of the outer peripheral part and the hard mask or the like as the upper film improves. Hence, even if the polishing pad is pressed on the surface of the outer peripheral part, the peeling of the hard mask or the like can be prevented.

The suction port may be placed so as to be allowed to suck the atmosphere in the vicinity of the predetermined portion from outside the substrate, and in this case, an atmospheric current which goes to the outside is formed above the outer peripheral part of the substrate, and therefore, the sloped part is easy to form, for example, at the end part of the film.

It is also possible that the film removing member has a shape which is composed of a vertical part, an upper part formed in a horizontal direction from an upper end part of the vertical part, and a lower part formed in the same direction as the horizontal direction from a lower end part of the vertical part, and is formed so that the outer peripheral part of the substrate is allowed to be inserted into an opening which is formed by the upper part and the lower part, and that the plasma supply part is attached to a ceiling surface inside the film removing member surrounded by the vertical part, the upper part, and the lower part. In this case, by inserting the outer peripheral part of the substrate inside the film removing member and supplying the plasma from the ceiling surface, the aforementioned formation of the slope part at the end part of the film and removal of the residue can be performed. Incidentally, the suction port may be provided inside the film removing member and at a position facing the opening.

Moreover, the plasma supply part may be provided in a portion facing the predetermined portion in the film removing member, and the suction port may be provided outside the plasma supply part. In this case, the suction ports may be provided facing to each other with the plasma supply part therebetween. In the film removing member thus structured, after the film is separated and removed by gas plasma supplied from the plasma supply part, components of the film can be sucked as they are from the suction port. Further, the formation of the sloped part is easy. Furthermore, by controlling the supply amount and the suction amount of the gas plasma, the slope degree of the sloped part can be adjusted. According to verification of the inventors, if the supply amount of gas plasma is increased, the slope of the sloped part becomes gentler, and if the suction amount from the suction port is increased, the slope becomes steeper.

The processing apparatus may further comprise a rotating mechanism for rotating the substrate, and in this case, it is possible to place the film removing member at a specific position of the outer peripheral part of the substrate and remove the film on the outer peripheral part of the substrate by rotating the substrate side. Moreover, the processing apparatus may further comprise a horizontal driving part for horizontally moving the film removing member. This horizontal driving part allows the film removing member to come close to or go away from the substrate. Accordingly, the film removing member can get access to the outer peripheral part of the substrate at a predetermined timing. Moreover, this horizontal driving part makes it possible to arbitrarily determine a removal range of the film on the outer peripheral part of the substrate and remove the film in a predetermined region on the outer peripheral part side of the substrate in accordance with a process. Further, a laser mark part in which substrate identification information such as a lot number, characteristics or the like of the substrate and a cut-out part (notch part) provided in the outer peripheral part of the substrate to facilitate the determination of the crystal orientation of the substrate can be partially removed.

The processing apparatus may further comprise a controlling part for controlling a suction pressure from the suction port. Since the suction pressure can be controlled, the flow path, flow rate, flow amount, and so on of the atmospheric current containing the plasma formed above the outer peripheral part of the substrate can be controlled. As a result, the film on the outer peripheral part can be removed in a predetermined shape.

The plasma supply parts may be provided at plural positions along a radial direction of the substrate in the film: removing member. Even where the supply range of one plasma supply part is narrow, the plasma can be supplied in a wider range at a time. Moreover, when film removal operations differ according to distances from the center of the substrate, plural removal operations can be performed at a time, for example, by changing the supply mount of plasma from each plasma supply part. Namely, the sloped part is formed at the end part of the outer peripheral film by the inner plasma supply part, and the residue on the surface of the outer peripheral part of the substrate can be removed by the outer plasma supply part. Further, the plasma supply parts may be provided at plural positions along a circumferential direction of the substrate in the film removing member. By providing the plasma supply parts at plural positions, the film in a wider range can be removed at a time, and the film removal operation can be made more speedy.

The plasma supply part may be an emitting part of a ray for converting the reactive gas into the plasma, and in this case, the reactive gas such as oxygen in the vicinity of the outer peripheral part of the substrate is converted into the plasma by emitting the ray, and this plasma is supplied to the film on the outer peripheral part. The film removing member may further include a reactive gas jetting part for jetting the reactive gas. This film removing member can actively supply the reactive gas in the vicinity of the outer peripheral part of the substrate, whereby the generation of the plasma by the ray is accelerated, and thereby the removal of the film by the plasma can be performed more certainly and in a shorter time.

The film removing member may include, in place of the plasma supply part, a laser radiating part for radiating a laser to the film on the predetermined portion of the outer peripheral part of the substrate or a liquid jetting part for jetting a liquid at a high pressure to the film on the predetermined portion of the outer peripheral part of the substrate. In the above case, the film on the predetermined portion of the outer peripheral part of the substrate can be physically cut and removed. Moreover, the film removing member may include, in place of the plasma supply part, an ultraviolet radiating part for radiating an ultraviolet ray to the film on the predetermined portion of the outer peripheral part of the substrate. This case is effective in a film such as an organic film which can be removed by radiating an ultraviolet ray.

The processing apparatus may further comprise an oxygen radical supply part for supplying oxygen radicals toward at least an outer peripheral part of a surface (for example, a rear surface), which is different from the surface on which the film is formed, of the substrate. When the oxygen radicals are supplied, organic matters or the like which adhere to or remain on the rear surface and the edge portion of the substrate can be effectively removed.

The processing apparatus may further comprise a heating unit such as an infrared lamp for heating the substrate by an infrared ray. This makes it possible to heat the substrate without touching it and accelerate a reaction. Accordingly, the time required for the removal of the film and the formation of the sloped part can be shortened.

The processing apparatus may further comprise, in addition to the film removing member, a removal solution discharge nozzle for discharging a removal solution to the outer peripheral part of the substrate to remove the film on the outer peripheral part or a coating solution discharge nozzle for discharging a coating solution to the substrate to form the film on the substrate. According to this processing apparatus, the aforementioned film forming processing and outer peripheral film removing processing performed after the film forming processing can be made in the same processing apparatus as the processing of removing the film on the predetermined portion of the outer peripheral part.

A processing method of the present invention is a processing method for processing a substrate on a surface of which a film is formed, comprising the step of forming in the film on an outer peripheral part of the substrate a sloped part such that its film thickness becomes thinner toward an end part.

According to the method of the present invention, when a hard mask which is an upper film or the like is formed later on the substrate and then subjected to polishing processing, the load of the polishing pad described above no longer concentrate on the film at the end part of the outer peripheral part. As a result, the peeling of the hard mask due to the intensive load no longer occurs, which can prevent the occurrence of particles and a product deficiency caused by peeling.

The processing method may further comprise the steps of: selectively removing the film on a portion of the outer peripheral part of the substrate; and forming the sloped part such that its film thickness becomes thinner toward the portion from which the film is removed. For example, the notch part and the laser mark part of the substrate can be selectively removed, whereby the occurrence of particles due to poor removal of the notch part and a substrate ID recognition error due to poor removal of the laser mark part can be prevented. Moreover, the sloped part such that its film thickness becomes thinner toward the portion from which the film is removed is formed, whereby the occurrence of particles due to the peeling of the upper film can be also prevented.

The processing method may further comprise the step of oxidizing a surface of the sloped part, and by this oxidation, the surface of the sloped part is reformed, and the adhesion to the later formed upper film improves, which prevents the upper film from peeling off even if a load is imposed thereon during the subsequent polishing processing.

A method of the present invention according to another aspect is a processing method for processing a substrate on a surface of which a film is formed, comprising the steps of: removing the film on an outer peripheral part of the substrate; and removing a residue of the film or the like adhering to the surface of the substrate of the outer peripheral part from which the film is removed.

According to this processing method, the residue of the film on the surface of the substrate is removed, and hence the adhesion between the surface of the substrate and the later formed upper film improves. As a result, for example, even if the polishing processing is thereafter performed by the polishing pad, the upper film does not peel off, and thereby the occurrence of particles and a product deficiency caused by the peeling can be prevented. Incidentally, also in this processing method, the step of oxidizing the surface of the substrate from which the residue is removed may be performed. By this oxidation, the surface of the substrate is reformed, and the adhesion between the surface of the substrate and the upper film improves, which can more certainly prevent the upper film from peeling off. It can be proposed to perform the aforementioned oxidation processing, for example, by supplying oxygen radicals. The oxygen radicals can be easily generated by the plasma, and therefore can be supplied to the substrate from the plasma supply part. Moreover, for example, if oxidation processing using oxygen plasma is performed after processing using a fluorine-based gas, it is possible to remove F atoms adhering to the surface and thereby improve the adhesion to the upper film.

According to still another aspect, a method of the present invention is a processing method for processing a substrate on a surface of which a film is formed, comprising the steps of: removing the film on an outer peripheral part of the substrate; removing a residue of the film or the like adhering to the surface of the substrate of the outer peripheral part from which the film is removed; and forming, at an end part of the film after the film is removed, a sloped part such that its film thickness becomes thinner toward the end part.

Also in this processing method, as in the aforementioned processing method, the sloped part is formed at the end part of the film, and the residue on the surface of the substrate from which the film is removed is removed, whereby the adhesion to the upper film which is applied later improves, and consequently the upper film no longer peels off during the polishing processing. Accordingly, the occurrence of particles and a product deficiency which are caused by the peeling of the upper film can be prevented. Incidentally, this processing method may comprise the step of oxidizing the surface of the substrate from which the residue is removed and a surface of the sloped part as in the aforementioned processing method.

Incidentally, the step of forming the sloped part and the removal of the residue may be performed while the substrate is heated. As a result, a reaction is accelerated, whereby the time required for the processing can be shortened.

### BRIEF DESCRIPTION OF THE DRAWINGS

FIG. 1 is a plan view showing an outline of the configuration of an SOD film forming system equipped with a costing unit according to an embodiment;

FIG. 2 is a front view of the SOD film forming system in FIG. 1;

FIG. 3 is a rear view of the SOD film forming system in FIG. 1;

FIG. 4 is an explanatory view of a vertical section showing an outline of the structure of the coating unit;

FIG. 5 is an explanatory view of a horizontal section of the coating unit in FIG. 4;

FIG. 6 is an explanatory view of a vertical section showing the structure of a film removing member;

FIG. 7 is an explanatory view of a vertical section of a wafer showing a situation in which a part of an outer peripheral film is removed by a removal solution discharge nozzle;

FIG. 8 is an explanatory view of the vertical section of the wafer showing a situation in which a sloped part is formed in the outer peripheral film;

FIG. 9 is an explanatory view of the vertical section of the film removing member showing a situation in which a position of a plasma releasing part is shifted;

FIG. 10 is an explanatory view of the vertical section of the film removing member showing a situation in which the position of the plasma releasing part is shifted gradually to form the sloped part in the outer peripheral film;

FIG. 11 is an explanatory view of the vertical section of the film removing member when plural plasma releasing parts are provided;

FIG. 12 is a plan view of a film removing member when plural plasma releasing parts are provided in a circumferential direction;

FIG. 13 is an explanatory view of a vertical section of a film removing member when a reactive gas supply port is provided in an upper part;

FIG. 14 is an explanatory view of a vertical section of a film removing member including a laser radiating part;

FIG. 15 is an explanatory view of a vertical section of a film removing member including a liquid jetting part;

FIG. 16 is a side view showing the structure of another film removing member having a plasma releasing part;

FIG. 17 is a bottom view of the film removing member in FIG. 16;

FIG. 18 is an explanatory view showing the situation of the sloped part when the supply amount of plasma is increased;

FIG. 19 is an explanatory view of the situation of the sloped part when the suction amount is increased;

FIG. 20 is an explanatory view showing a situation around a spin chuck where an infrared lamp is placed; and

FIG. 21 is an explanatory view of a vertical section of a wafer showing the situation of conventional polishing processing by a polishing pad.

### BEST MODE FOR CARRYING OUT THE INVENTION

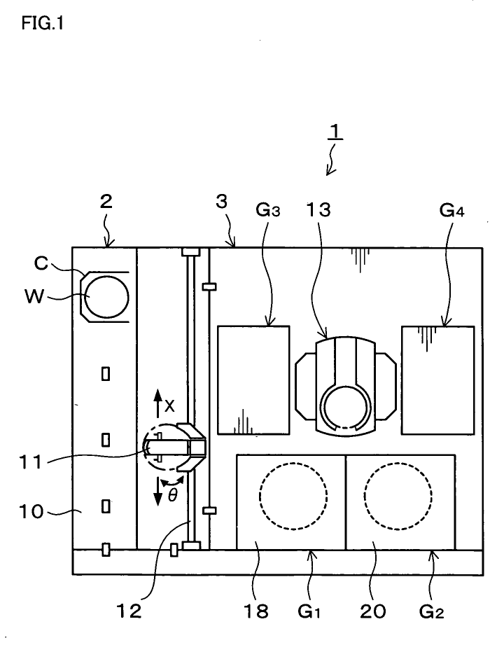

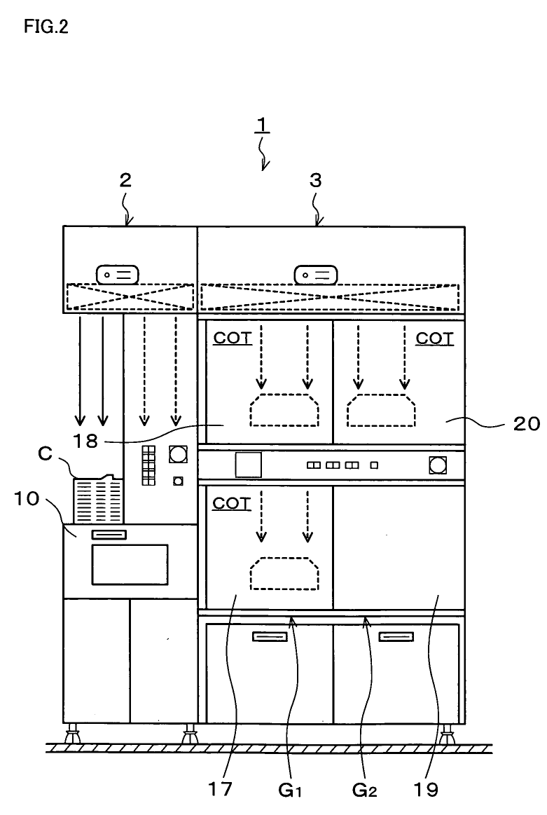

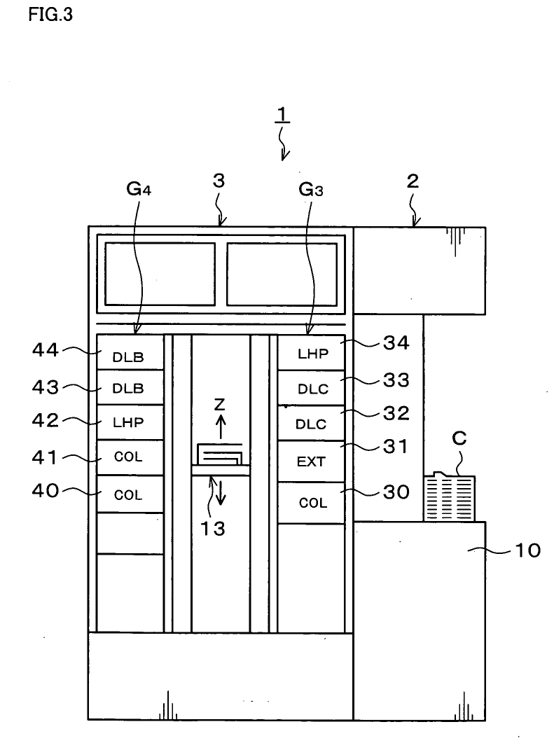

A preferred embodiment of the present invention will be explained below. FIG. 1 is a plan view showing an outline of the configuration of an SOD film forming system 1 equipped with a processing apparatus according to this embodiment, FIG. 2 is a front view of the SOD film forming system 1, and FIG. 3 is a rear view of the SOD film forming system 1. This SOD film forming system 1 is, for example, a processing system for forming an interlayer insulating film (Low-K film) having a low dielectric constant on a wafer W.

As shown in FIG. 1, the SOD film forming system 1 has a structure in which a cassette station 2 for carrying, for example, 25 wafers W per cassette, as a unit, from/to the outside into/from the SOD film forming system 1 and carrying the wafer W into/out of a cassette C and a processing station 3 in which various kinds of processing units each for performing predetermined processing for the wafers W one by one in an SOD film forming process are stacked in multiple tiers are integrally connected.

In the cassette station 2, a plurality of cassettes C can be freely mounted in a line in an X-direction (in a top-bottom direction in FIG. 1) at predetermined positions on a cassette mounting table 10 which is a mounting part. A wafer carrier 11 which is movable in a direction of arrangement of the cassettes (the X-direction) and in a direction of arrangement of the wafers W housed in the cassette C (a Z-direction; vertical direction) can freely move along a carrier guide 12 and selectively get access to each of the cassettes C.

The wafer carrier 11 has an alignment function of aligning the wafer W. This wafer carrier 11 is structured to be able to get access to an extension unit 31 included in a third processing unit group G3 on the processing station 3 side as will be described later.

In the processing station 3, a main carrier unit 13 is disposed in the middle thereof, and around the main carrier unit 13, various kinds of processing units are stacked in multiple tiers to compose processing unit groups. In this SOD film forming system 1, four processing unit groups G1, G2, G3, and G4 are disposed, the first and second processing unit groups G1 and G2 are disposed on the front side of the SOD film forming system 1, the third processing unit group G3 is disposed adjacent to the cassette station 2, and the fourth processing unit group G4 is disposed on the side opposite to the third processing unit group G3 with the main carrier unit 13 therebetween. The main carrier unit 13 can carry the wafer W into/out of under-mentioned various processing units disposed in these processing unit groups G1, G2, G3, and G4. Incidentally, the number and disposition of processing unit groups differ according to the sort of processing performed on the wafer W and can be arbitrarily selected.

In the first processing unit group G1, for example as shown in FIG. 2, coating units 17 and 18 each as a processing apparatus according to this embodiment are stacked in two tiers in order from the bottom. In the second processing unit group G2, a processing solution cabinet 19 which stores, for example, a coating solution or the like used in the coating unit 17 or the like and serves a source of supply of the coating solution or the like and a coating unit 20 are stacked in two tiers in order from the bottom.

In the third processing unit group G3, for example as shown in FIG. 3, a cooling unit 30 for subjecting the wafer W to cooling processing, an extension unit 31 for delivering the wafer W, curing units (low-oxygen and high-temperature curing units with cooling) 32 and 33 for subjecting the wafer W to curing processing, a low-temperature heating processing unit 34 for subjecting the wafer W to heating processing at a low temperature are stacked in five tiers in order from the bottom.

In the fourth processing unit group G4, for example, cooling units 40 and 41, a low-temperature heating processing unit 42, and low-oxygen heating processing units 43 and 44 for subjecting the wafer W to heating processing in a low-oxygen atmosphere are stacked, for example, in five tiers in order from the bottom.

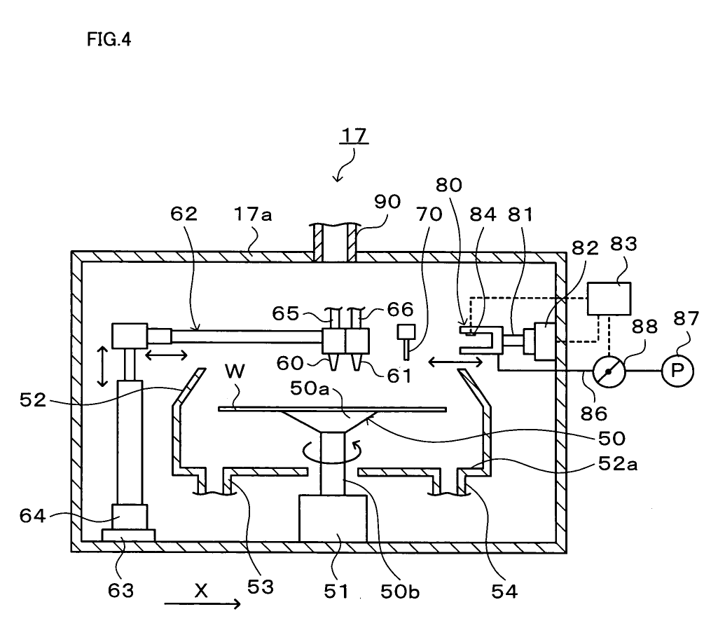

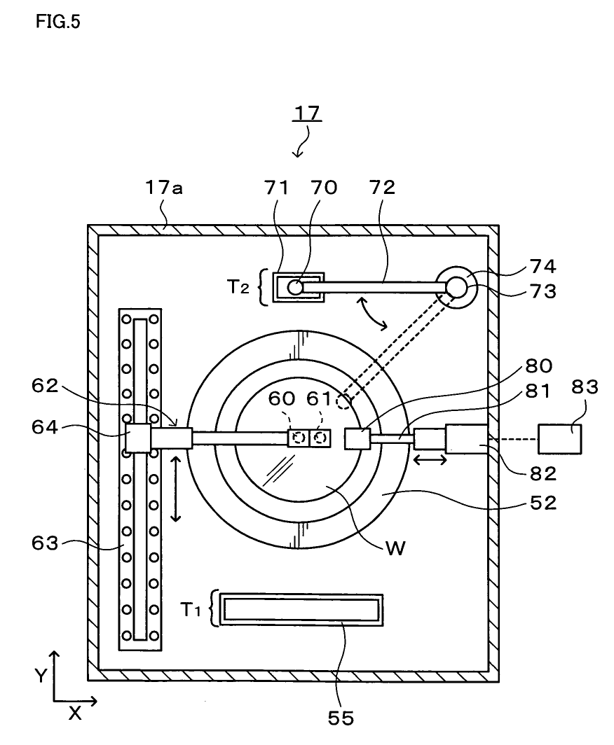

Next, the structure of the aforementioned coating unit 17 will be explained in detail. FIG. 4 is an explanatory view of a vertical section showing an outline of the structure of the coating unit 17, and FIG. 5 is an explanatory view of a horizontal section of the coating unit 17.

For example, as shown in FIG. 4, the coating unit 17 includes a casing 17a, and a spin chuck 50 for holding and rotating the wafer W is provided in this casing 17a. This spin chuck 50 is, for example, composed mainly of a holding part 50a on which the wafer W is held, for example, and a vertical shaft 50b which supports the holding part 50a from below.

An upper surface of the holding part 50a is formed horizontally and provided with a suction port not shown, for example, for holding the wafer W by suction. Consequently, the spin chuck 50 can horizontally hold the wafer W by suction. The vertical shaft 50b works, for example, with a rotation driving part 51 including a motor or the like provided below the spin chuck 50 and can rotate at a predetermined rotation speed by this rotation driving part 51. Accordingly, the wafer W held by the spin chuck 50 can be rotated at the predetermined speed by the rotation driving part 51. The rotation driving part 51 further includes a cylinder, for example, which moves the vertical shaft 50b up or down, and thereby it can move the entire spin chuck 50 up or down. Incidentally, in this embodiment, the spin chuck 50 and the rotation driving part 51 compose a rotating mechanism.

Provided outside the spin chuck 50 is a cup 52 for catching and collecting the coating solution or the like which is scattered from the wafer W. The cup 52 has an almost cylindrical shape with its upper surface open, and it is formed so as to surround the outside and the bottom of the wafer W. A drain pipe 53 for draining the collected coating solution or the like and an exhaust pipe 54 for exhausting an atmosphere in the cup 52 are connected to a lower surface 52a of the cup 52.

As shown in FIG. 5, a nozzle waiting part T1 is placed on the outside of the cup 52, for example, on the outside thereof on the negative Y-direction side (on the downward direction side of FIG. 5). This nozzle waiting part T1 is a waiting part of a coating solution discharge nozzle 60 and a solvent discharge nozzle 61 which will be described later. In the nozzle waiting part T1, for example, a first nozzle bath 55 is placed. A solvent vapor jetting port not shown, for example, is provided in the first nozzle bath 55, and the first nozzle bath 55 can be filled with a solvent atmosphere. Therefore, the coating solution discharge nozzle 60 and the solvent discharge nozzle 61 which are waiting can be maintained in the solvent atmosphere.

As shown in FIG. 4, the coating solution discharge nozzle 60 and the solvent discharge nozzle 61 are held by a nozzle arm 62 in such a manner that their discharge ports point downward. As shown in FIG. 5, in the casing 17a, a rail 63 which extends from the nozzle waiting part Ti to the vicinity of the cup 52 along the Y-direction (the top-bottom direction in FIG. 5) is laid. The rail 63 is provided, for example, on the negative X-direction side of the cup 52 (the left side of FIG. 5). The nozzle arm 62 can move on the rail 63 in the Y-direction by an arm driving part 64 including a motor, a cylinder, and so on.

For example, the nozzle arm 62 can be freely extended and contracted in the X-direction and the Z-direction by the arm driving part 64. As just described, the nozzle arm 62 can three-dimensionally move in the X-, Y-, and Z-directions. Accordingly, the nozzle arm 62 can carry the coating solution discharge nozzle 60 and the solvent discharge nozzle 61 from the nozzle waiting part T1 to a predetermined discharge position above a central part of the wafer W.

As shown in FIG. 4, the coating solution discharge nozzle 60 communicates with a coating solution supply unit not shown by a coating solution supply pipe 65, and a predetermined flow rate of coating solution can be discharged from the coating solution discharge nozzle 60 at a predetermined timing. The coating solution discharged from the coating solution discharge nozzle 60 is, for example, a solution in which siloxane-based polymer as a material for an insulating film and its solvent are mixed. Moreover, the solvent discharge nozzle 61 communicates with a solvent supply unit not shown by a solvent supply pipe 66, and a solvent is discharged from the solvent discharge nozzle 61 at a predetermined timing.

As shown in FIG. 5, a waiting part T2 of a removal solution discharge nozzle 70 is placed on the positive Y-direction side of the cup 52 in the casing 17a. The removal solution discharge nozzle 70 discharges a removal solution for a coating film to an outer peripheral part of the wafer W. In the waiting part T2, for example, a second nozzle bath 71 which can maintain a solvent atmosphere in the bath is provided. The removal solution discharge nozzle 70 is held, for example, by a pivoting arm 72. The pivoting arm 72 is attached, for example, to a supporting post 73 which is a pivot, and the supporting post 73 works with a pivoting arm driving part 74. The pivoting arm driving part 74 is provided with a servo motor not shown for turning the supporting post 73 by a predetermined angle. By turning the supporting post 73, the pivoting arm 72 is turned to allow the removal solution discharge nozzle 70 to reciprocate between the waiting part T2 and the outer peripheral part of the wafer in the cup 52. Moreover, the pivoting arm driving part 74 is provided with a cylinder not shown for moving the pivoting arm 72 up or down and so on, and can adjust the distance between the removal solution discharge nozzle 70 and the wafer W, for example.

As shown in FIG. 4 and FIG. 5, a film removing member 80 for removing a film on a predetermined portion of the outer peripheral part of the wafer W is provided in the casing 17a and on the side opposite to the rail 63 with the cup 52 therebetween, that is, on the positive X-direction side.

The film removing member 80 is supported, for example, by one end of a horizontal supporting arm 81. The other end of the supporting arm 81 is attached to a side surface on the positive X-direction side of the casing 17a and at a position facing a central part of the spin chuck 50. Namely, the film removing member 80 is disposed on an X-axis which passes the central part of the wafer W held by the spin chuck 50. The supporting arm 81 includes a horizontal driving part 82 which includes a cylinder for horizontally moving the film removing member 80 in the X-direction or the like. Thereby, the film removing member 80 can freely come close to or go away from the wafer W held by the spin chuck 50, and can get access to the wafer W from the side of the wafer W. Incidentally, the movement of the horizontal driving part 82 is controlled, for example, by a controlling part 83, and this control makes it possible to move the film removing member 80 to a predetermined position at a predetermined timing.

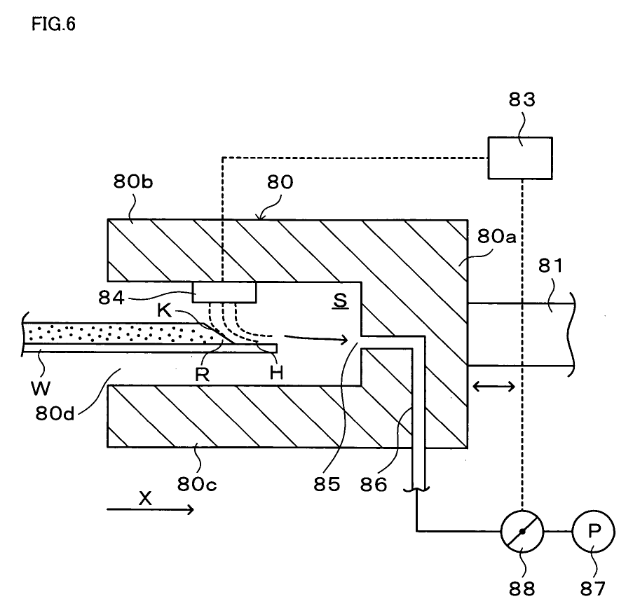

As shown in FIG. 6, the film removing member 80 is composed mainly of a vertical part 80a, an upper part 80b which protrudes from an upper end part of the vertical part 80a to the negative X-direction side in a horizontal direction, a lower part 80c which protrudes from a lower end part of the vertical part 80a to the negative X-direction side in the horizontal direction, and has an almost reversed C shape in side view. In other words, an opening 80d of the film removing member 80 is located on the negative X-direction side. A space between the upper part 80b and the lower part 80c is at least ten times as long as the thickness of the wafer W, for example, approximately 7.5 mm, and the upper part 80b and the lower part 80c form a gap part S into which the outer peripheral part of the wafer W can be inserted.

A plasma releasing part 84 as a plasma supply part for releasing plasma downward is attached to the inner side of the film removing member 80, that is, a ceiling surface of the gap part S. The plasma has a function of touching the coating film formed on the wafer W and chemically reacts with the touched portion to thereby liberate the touched portion from the coating film. The plasma releasing part 84 releases plasma, which is generated by a plasma generating part not shown, at a predetermined flow rate. The release of the plasma from the plasma releasing part 84 is controlled, for example, by the controlling part 83. This controlling part 83 makes it possible to supply the plasma to an outer peripheral film of the wafer W at a predetermined timing.

A suction port 85 is bored in a side surface of the gap part S, that is, the inner side of the vertical surface 80a of the film removing member 80 and at a position facing the opening 80d. The suction port 85, for example, communicates with a suction pipe 86 which passes through the vertical part 80a. The suction pipe 86 is connected, for example, to a suction pump 87 as a negative pressure generating means outside the unit. The suction pipe 86 is provided, for example, with an adjusting damper 88, and this adjusting damper 88 makes it possible to adjust a suction pressure from the suction port 85. The operation of the adjusting damper 88 is controlled, for example, by the controlling part 83. This structure makes it possible to form an atmospheric current which goes from the plasma releasing part 84 side to the suction port 85 in the gap part S, and further control the suction pressure of the suction port 85 to change a flow path of the atmospheric current containing the plasma from the plasma releasing part 84. In other words, by increasing the suction pressure, an inclination of a plasma current with respect to a horizontal surface can be reduced, and by decreasing the suction pressure, the inclination of the plasma current can be increased. Accordingly, by controlling the suction pressure, the shape of the film eroded by the plasma can be changed.

On the other hand, a duct 90 for supplying a gas such as a cleaned nitrogen gas, inert gas, air, or the like whose temperature and humidity are regulated into the cup 52 is connected to an upper part of the casing 17a, and by supplying the gas during the processing of the wafer W, a predetermined atmosphere can be maintained in the cup 52.

Next, the operation of the coating unit 17 structured as above will be explained with an insulating film forming process performed in the SOD film forming system 1.

First, one unprocessed wafer W is taken out of the cassette C by the wafer carrier 11 and carried to the extension unit 31 included in the third processing unit group G3. Then, the wafer W is carried to the cooling unit 30 by the main carrier unit 13 and cooled to a predetermined temperature. The wafer W cooled to the predetermined temperature is carried to the coating unit 17 by the main carrier unit 13.

The wafer W subjected to predetermined processing described later in the coating unit 17 is carried to the low-temperature heating processing unit 34 or 42 and the low-oxygen heating processing unit 43 or 44 in sequence by the main carrier unit 13, and carried to the curing unit 32 after the solvent in the coating film is vaporized.

The wafer W subjected to curing processing in the curing unit 32 is carried to the cooling unit 30 to be cooled, and thereafter returned to the extension unit 31. The wafer W returned to the extension unit 31 is carried to the cassette C by the wafer carrier 11, and the successive insulating film forming process is completed.

Next, a processing process performed in the aforementioned coating unit 17 will be explained. First of all, before the wafer W is carried into the coating unit 17, the supply of clean air regulated, for example, at 23° C. from the duct 90 is started, and on the other hand, the exhaust from the exhaust pipe 54 of the cup 52 is started. Consequently, an atmosphere at a predetermined temperature is maintained in the cup 52, and particles occurring during processing can be removed.

Then, when the cooling processing in the cooling unit 30 which is preprocessing is completed, the wafer W is carried into the casing 17a by the main carrier unit 13 and delivered to the spin chuck 50 which is waiting in advance above the cup 52. Subsequently, the spin chuck 50 lowers, and the wafer W is housed in the cup 52. When the wafer W is housed in the cup 52, the solvent discharge nozzle 61 which has been waiting at the nozzle waiting part T1 is moved to the predetermined position above the central part of the wafer W by the nozzle arm 62. Then, a predetermined amount of solvent is discharged from the solvent discharge nozzle 61 to the central part of the wafer W.

When the predetermined amount of solvent is discharged onto the wafer W, the wafer W is rotated at high speed by the rotation driving part 51, and the solvent on the wafer W is spread over the entire surface of the wafer. Thereafter, by continuing rotating the wafer W, the solvent on the wafer W is dried or thrown off. By the aforementioned supply and drying of the solvent, impurities such as dust adhering onto the wafer W are removed, and hence the wettability of the wafer W with respect to the coating solution improves. Thereafter, for example, the rotation of the wafer W is temporarily stopped.

Then, the nozzle arm 62 extends and contracts in the X-direction, and as shown in FIG. 4, the coating solution discharge nozzle 60 moves to the discharge position above the central part of the wafer W. When the coating solution discharge nozzle 60 stops at the discharge position, a predetermined amount of coating solution is discharged to the central part of the wafer W. Thereafter, the wafer W is rotated, the coating solution on the wafer W is spread by this rotation, and the coating solution is spread over the entire surface of the wafer W. As a result, the coating film having a predetermined thickness is formed on the wafer W. Incidentally, this coating film becomes an insulating film by passing the aforementioned successive insulating film forming process. Moreover, a predetermined region on the side of an outer edge part of this coating film, for example, a region of 2 mm from an end part of the wafer W becomes an outer peripheral film which is an unnecessary portion.

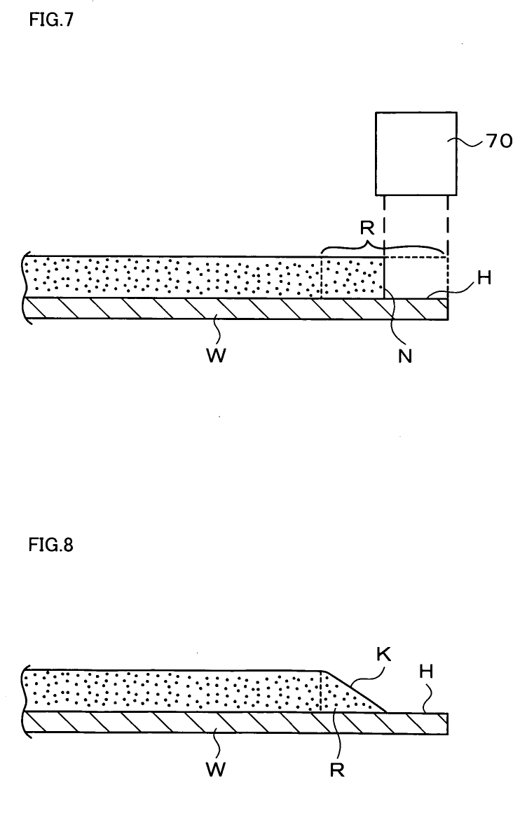

When the coating film having the predetermined thickness is formed on the wafer W, the wafer W is rotated at low speed, for example, at 2 rpm to 100 rpm, and more preferably, at 40 rpm to 60 rpm, and the removal solution discharge nozzle 70 which has been waiting at the waiting part T2 moves to above the outer peripheral film of the wafer W. Then, as shown in FIG. 7, the removal solution is discharged to a predetermined region on the end part side within an outer peripheral film R of the wafer W, for example, a region of approximately 1.5 mm from the end part, and thereby the outer peripheral film R on the outer side is annularly removed. As a result of the removal of the outer peripheral film R, a vertical surface N is formed at an end surface of the outer peripheral film R. Further, in a portion from which the film is removed, the surface of the wafer W is exposed, and a flat surface H is formed.

When the removal of the end part side of the peripheral film R is completed, the removal solution discharge nozzle 70 withdraws to the waiting part T2, and, for example, the rotation of the wafer W is temporarily stopped. Subsequently, the wafer W is moved to above the cup 52, for example, by the spin chuck 50. Then, the film removing member 80 which has been waiting outside the cup 52 moves to the negative X-direction side, and as shown in FIG. 6, the outer peripheral part of the wafer W is inserted into the gap part S of the film removing member 80. At this time, the plasma releasing part 84 is placed above the end part of the outer peripheral film R remaining on the wafer W. Thereafter, the wafer W starts to be rotated at low speed, for example, at approximately 3 rpm. It is needless to say that the number of rotations is not limited to this example, and any number of rotations from 2 rpm to 100 rpm can be used.

Moreover, plasma is released from the plasma releasing part 84 and at the same time, an atmosphere in the gap part S is sucked from the suction port 85. Consequently, as shown in FIG. 6, a plasma current which goes from the plasma releasing part 84 to the outside of the wafer W through the vicinity of the end part of the outer peripheral film R of the wafer W is formed. Then, the plasma released from the plasma releasing part 84 touches the outer peripheral film R while flowing to the suction port 85 side and obliquely erodes the end part of the outer peripheral film R. As a result, as shown in FIG. 8, a sloped part K along an atmospheric current is formed at the end part of the outer peripheral film R. Further, the suction pressure of the suction port 85 is controlled, and thereby the sloped part K is formed in such a manner that its base is approximately 0.5 mm and its angel of slope is approximately 0.17×10⁻⁴.

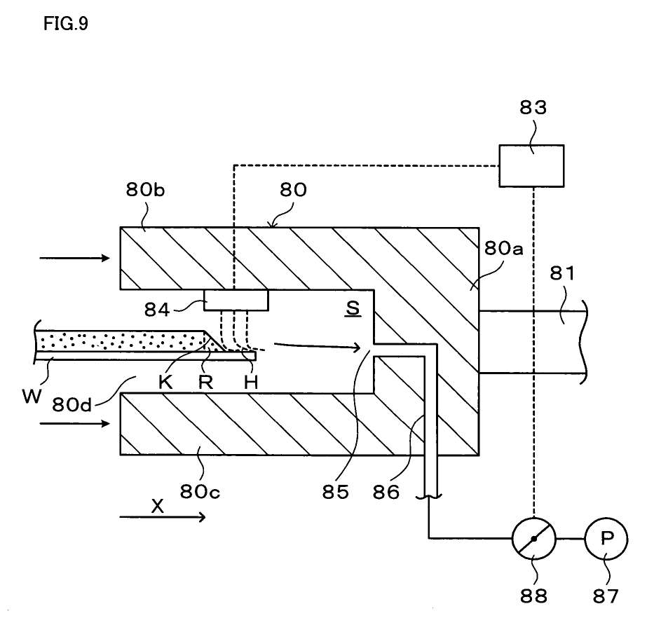

When the sloped part K is formed at the end part of the outer peripheral film R, as shown in FIG. 9, the film removing member 80 slightly moves to the positive X-direction side while the plasma continues being released, and the plasma releasing part 84 stops above the flat surface H. Incidentally, the suction from the suction port 85 continues being performed. The plasma is released for a predetermined period of time from the plasma releasing part 84 above the flat surface H, and thereby a residue of the film and organic matters adhering onto the flat surface H is removed. When the residue on the flat surface H is removed, the release and suction of the plasma is stopped, and the film removing member 80 withdraws to the outside of the cup 52. At this time, the rotation of the wafer W is also stopped.

When the rotation of the wafer W is stopped, the wafer W is delivered from the spin chuck 50 to the main carrier unit 13, the wafer W is carried out of the casing 17a, and the successive processing process in the coating unit 17 is completed.

According to the aforementioned embodiment, the film removing member 80 including the plasma releasing part 84 and the suction port 85 is provided in the coating unit 17, a predetermined portion of the outer peripheral film R can be selectively removed. Hence, the sloped part K can be formed at the end part of the outer peripheral film R. As a result, even if the wafer W is later polished by a polishing pad or the like, a load of the polishing pad is not imposed intensively on the end part of the outer peripheral film R. Accordingly, for example, a hard mask formed on the outer peripheral film R can be prevented from peeling off due to the intensive load of the polishing pad. Further, the residue of the film adhering onto the flat surface H can be removed by the film removing member 80. As a result, the adhesion between the flat surface H and the hard mask as an upper film formed later improves, which can prevent the hard mask from peeling from the flat surface H due to the polishing pad during polishing processing. Therefore, the occurrence of particles, a product deficiency of the wafer W, and the like caused by peeling can be prevented.

Furthermore, the controlling part 83 for controlling the suction pressure of the suction port 85 is provided, whereby a flow path of the plasma current flowing above the outer peripheral film R can be controlled. Therefore, the sloped part K having a predetermined shape can be formed in the outer peripheral film R which is eroded by the plasma current. Namely, the sloped part K can be formed at a desired slope angle in a desired position.

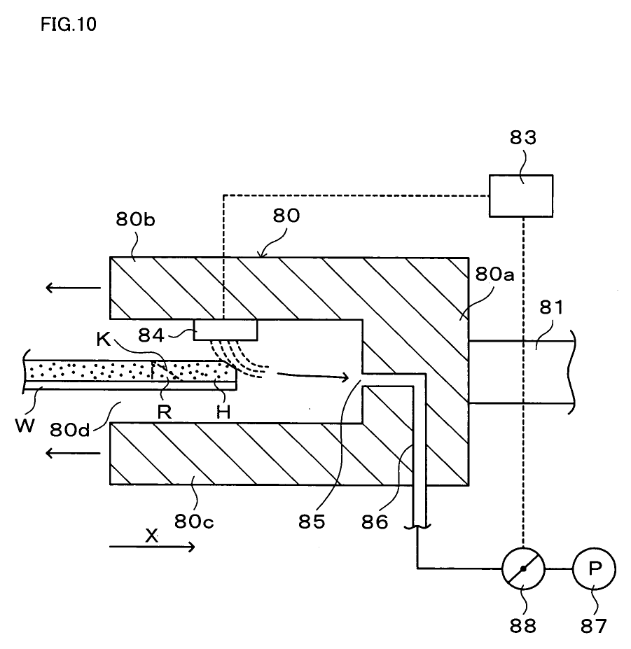

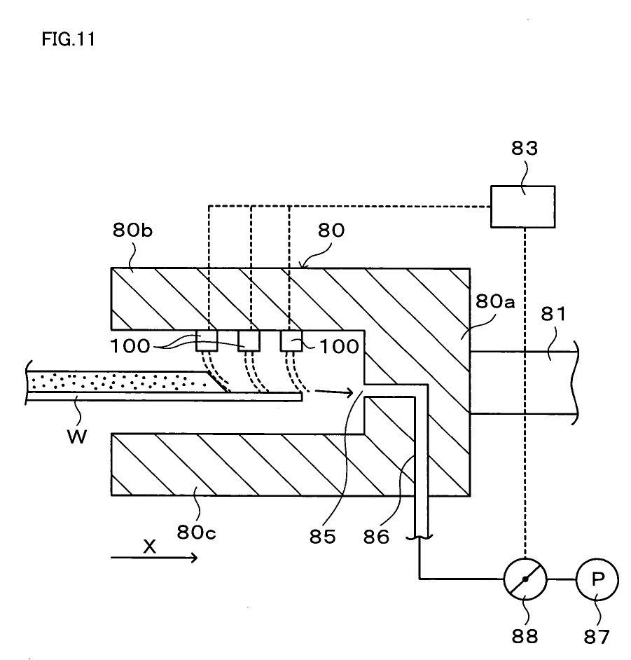

In the aforementioned embodiment, after an outermost part of the outer peripheral film R is first removed by the removal solution from the removal solution discharge nozzle 70, the sloped part K is formed at the end part of the remaining outer peripheral film R by the film removing member 80, but instead of performing the removal of the outermost part by the removal solution discharge nozzle 70, the sloped part K may be formed at the end part of the outer peripheral film R while the outer peripheral film R is removed by the film removing member 80 after the insulating film is formed. For example, as shown in FIG. 10, while the plasma is released from the plasma releasing part 84 and the suction from the suction port 85 is performed, the film removing member 80 moves above the outer peripheral film R in a radial direction. For example, the plasma releasing part 84 moves from above an outer end part of the wafer W to above an inner end part thereof. In so doing, the outer peripheral film R is gradually shaved from the outside, and eventually the same flat surface H and sloped part K as in the aforementioned embodiment are formed.

Moreover, in the aforementioned embodiment, both the formation of the sloped part K and the removal of the residue on the flat surface H are performed by the film removing member 80, but only either one may be performed. When only the removal of the residue on the flat surface H is performed, first, the entire 2 mm wide outer film peripheral R which is the unnecessary portion is removed by the removal solution discharge nozzle 70. By this removal, the 2 mm wide flat surface H is formed on the outer peripheral part of the wafer W. Then, the film removing member 80 moves, and the plasma releasing part 84 is placed above the flat surface H. Thereafter, the plasma is released from the plasma releasing part 84 toward the flat surface H, and the suction from the suction port 85 is performed. Thus, the residue of the insulating film and the like adhering onto the flat surface H is removed as in the aforementioned embodiment. As a result, the adhesion between the flat surface H and the hard mask formed later improves, and the peeling of the hard mask is prevented.

In the aforementioned embodiment, it is also possible that after the sloped part K is formed, the plasma is supplied again to the sloped part K to oxidize the surface of the sloped part K. In so doing, the adhesion between the hard mask formed later and the sloped part K further improves, and, for example, even when being pressed by the polishing pad, the hard mask no longer peels off.

When a fluorine-based gas, for example, a gas obtained by converting CF₄ into plasma is supplied as the plasma released from the plasma releasing part, if oxidizing processing by oxygen plasma is performed as later oxidizing processing, F atoms adhering to the surface can be removed by the oxygen plasma, which can further improve the adhesion to the hard mask, leading to an increase in the effect of preventing the peeling of the hard mask. Moreover, the plasma may be supplied again also to the flat surface H from which the residue is removed to oxidize this flat surface H. Also in this case, the adhesion between the flat surface H and the hard mask improves, which can prevent the hard mask from peeling off.

In the processing process described in the above embodiment, it is also possible to selectively remove a part of the coating film, for example, the coating film at a notch part, a laser mark part, or an ID mark part of the outer peripheral part of the wafer and form a sloped part such that its film thickness becomes thinner toward the removed part. For example, after the sloped part K is formed at the outer peripheral part of the wafer W, the wafer W is rotated by a predetermined angle to move the notch part of the wafer W to a position facing the plasma releasing part 84. Thereafter, the plasma current is supplied from the film removing member 80 to the outer peripheral film R on the notch part to remove the outer peripheral film R on the notch part. Moreover, the obliquely flowing plasma current which is the same as in the aforementioned embodiment is also supplied to the outer peripheral film R around the notch part, whereby the sloped part such that its film thickness becomes thinner toward the notch part is formed. As a result, the coating film on the notch part is removed, which allows a sensor to certainly detect the notch part. Further, since the sloped part is also formed in the coating film facing the notch part, even if the hard mask is formed later and pressed from above by a cleaning brush, an intensive load is not imposed on the end portion of the coating film facing the notch part, which prevents the coating film at this portion from peeling off.

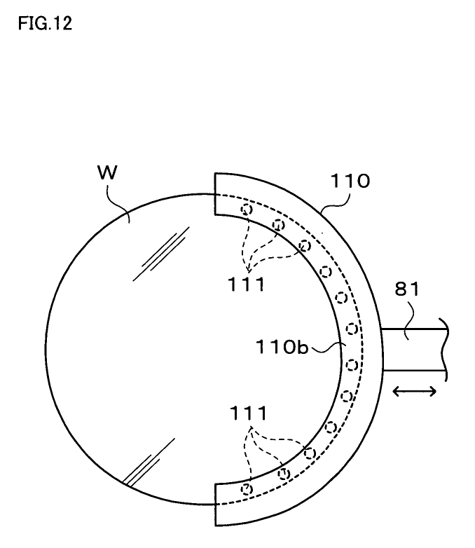

The plasma releasing parts 84 described in the aforementioned embodiment may be provided at plural positions of the film removing member 80. For example, as shown in FIG. 11, plural, for example, three plasma emitting parts 100 may be provided side by side in the radial direction of the wafer W. In this case, even where the emission range of one plasma emitting part 100 is narrow, the wide outer peripheral film R can be removed without moving the film removing member 80. Further, the formation of the sloped part K and the removal of the residue on the flat surface H can be performed at the same time. On the other hand, as shown in FIG. 12, it is also possible to form a film removing member 110 in an arc shape along the shape of the wafer W and attach plural plasma emitting parts 111 to an upper part 110B of the film removing member 110 at even intervals. In this case, the film in a wider range can be removed at the same time, and hence the time required for a removal operation can be shortened. Furthermore, as shown in FIG. 12, an arc of the film removing member 110 may have an interior angle of 180° or less, and in this case, the film removing member 110 can get access to the wafer W from the side of the wafer W. Incidentally, the film removing member 110 may have a ring shape.

In the aforementioned embodiment, the plasma removing member 80 is provided with the plasma releasing part 84 to remove a predetermined portion of the outer peripheral film R, but an emitting part of a ray, for example, an ultraviolet ray may be provided in place of the plasma releasing part 84. Also in this case, oxygen in the atmosphere is converted into plasma by the emitted ultraviolet ray and the predetermined portion of the outer peripheral film R is removed by this plasma. Accordingly, the sloped part K can be formed at the end part of the outer peripheral part R while being accompanied by the suction from the suction port 85. Further, the residue on the flat surface H formed at an outermost peripheral part of the wafer W can also be removed.

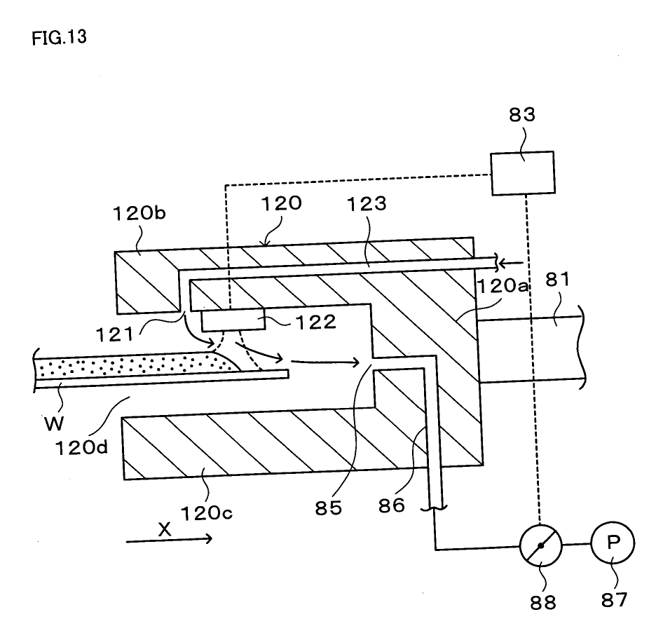

When the film removing member 80 is provided with the emitting part of the ultraviolet ray, as shown in FIG. 13, a film removing member 120 may include a reactive gas supply port 121 of a reactive gas such as oxygen. The reactive gas supply port 121 is provided, for example, in an upper part 120b of the film removing member 120 and at a position adjacent to an ultraviolet emitting part 122. The reactive gas supply port 121 is provided, for example, on the upstream side, that is, the negative X-direction side of the ultraviolet emitting part 122. The reactive gas supply port 121 communicates with a supply pipe 123 which passes through the upper part 120b. This supply pipe 123 communicates, for example, with a reactive gas supply unit not shown. When an ultraviolet ray is radiated, oxygen is jetted from the reactive gas supply port 121. The jetted oxygen is converted into plasma by the ultraviolet ray and erodes the outer peripheral film R. In this case, since the reactive gas which becomes the plasma is actively supplied, the formation of the sloped part K at the end part of the outer peripheral film R can be more certainly and rapidly performed. Incidentally, the number of the reactive gas supply ports 121 is not limited to one, and may be more than one. Moreover, by controlling the supply pressure of the reactive gas and the suction pressure from the suction port 85, the atmospheric current formed in the gap part S may be controlled more strictly. Further, the suction port 85 may be provided in the upper part 120b and outside the reactive gas supply port 121. In this case, the reactive gas is introduced from above, touches the outer peripheral film R, and thereafter is exhausted again from above. By controlling the introduction amount and exhaust amount of the reactive gas at this time, a desired atmospheric current is formed above the outer peripheral film R, and thereby the outer peripheral film R can be formed in a predetermined shape. Namely, the sloped part K can be formed at the end part of the outer peripheral film R. Incidentally, the ray may be an electron beam without being limited to the ultraviolet ray.

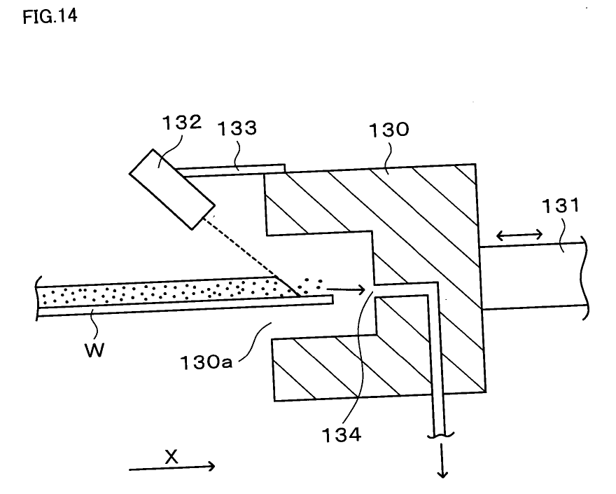

As shown in FIG. 14, a laser radiating part 132 in place of the plasma releasing part may be attached to a film removing member 130. This film removing member 130 has an almost reversed C shape similarly to the film removing member 80 described in the aforementioned embodiment, and it is supported by a supporting arm 131. The laser radiating part 132 is supported, for example, by a supporting member 133 attached to the film removing member 130. The laser radiating part 132 is attached in a depression angle direction which leans in the positive X-direction from a downward direction. Moreover, a suction port 134 which is the same as that in the aforementioned embodiment is provided inside the film removing member 130 and at a position facing an opening 130a. A laser is radiated obliquely toward the outer peripheral film R on the rotating wafer W on one hand, and an atmosphere in the vicinity of the outer peripheral film R is sucked from outside the wafer W on the other hand. By so doing, the end part of the outer peripheral film R is physically cut off obliquely, this cut film is removed from the suction port 134, and the sloped part K is formed in the outer peripheral film R. Incidentally, the laser radiating part 131 in FIG. 14 may be an ultraviolet radiating part. Since specific kinds of films including an organic film are dissolved by an ultraviolet ray, the end part of the outer peripheral film R can be removed obliquely by the radiation of the ultraviolet ray by the ultraviolet radiating part.

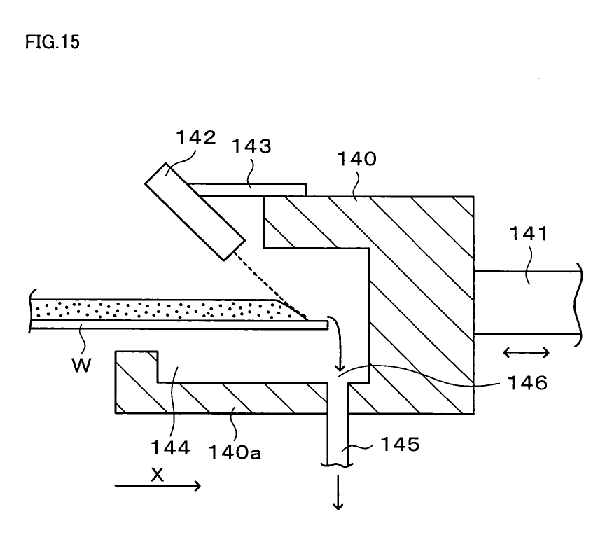

Moreover, as shown in FIG. 15, a liquid jetting part 141 in place of the plasma releasing part may be attached to a film removing member 140. This film removing member 140 also has an almost reversed C shape similarly to the film removing member 80 described in the aforementioned embodiment or the like, and it is supported by a supporting arm 141. The liquid jetting part 142 is supported, for example, by a supporting member 143 attached to the film removing member 140. The liquid jetting part 142 is attached in the depression angle direction which leans in the positive X-direction from the downward direction. In a lower part 140a of the film removing member 140, a concave collecting part 144 capable of collecting jetted liquid, for example, is formed. An outlet 146 which communicates with an outlet pipe 145 is bored in a lower surface of the colleting part 144, and the liquid collected by the colleting part 144 can be drained. Incidentally, the outlet pipe 145 is connected to a drain tank on the factory side not shown. When the outer peripheral film R is cut, a high-pressure, for example, 0.5 kPa liquid is jetted obliquely to the outer peripheral film R of the rotating wafer W. The jetted liquid is collected by the collecting part 144 and let out from the outlet 146. As a result, the end part of the outer peripheral film R is cut off obliquely, and thereby the sloped part K is formed in the outer peripheral film R. Incidentally, as the liquid, for example, a liquid which is hardly soluble in the coating film such as isopropyl alcohol (IPA) is used.

Incidentally, in place of the laser radiating part 132 or the liquid jetting part 142, a microwave generating part, an ion beam radiating part, an ERC (electron cyclotron resonance) generating part, or the like, may be provided to remove the predetermined portion of the outer peripheral film R.

The film removing members 80, 110, 120, 130, and 140 described in the aforementioned embodiment are provided in the coating unit 17, but they may be provided in an independent processing unit including a rotating mechanism for rotating the wafer W. Moreover, when a film removing processing unit for the outer peripheral film, which is provided with the removal solution discharge nozzle 70, is provided in addition to the coating unit 17, the film removing member may be provided in this film removing processing unit.

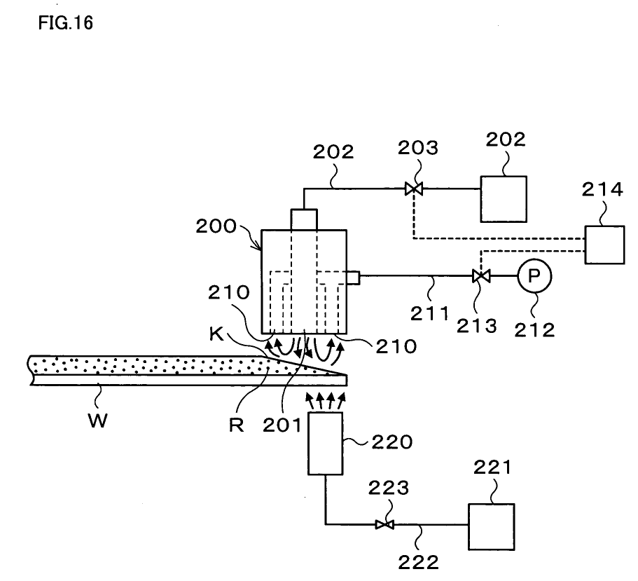

In place of the film removing member 80 having the plasma releasing part 80 out of the film removing members used in the aforementioned embodiment, a film removing member 200 shown in FIG. 16 may be used. This film removing member 200 has an almost cylindrical nozzle shape as its whole shape. A plasma releasing part 201 has the structure of a release port as shown in FIG. 17 and it is formed in a bottom surface of the film removing member 200. Namely, it is located in a portion facing the outer peripheral film R which is a film on a predetermined portion corresponding to the outer periphery of the wafer W. Gas plasma from a plasma generator 202 is introduced into the film removing member 200 through a supply pipe 203 and supplied from the plasma releasing part 201 formed in the bottom surface of the film removing member 200 to the wafer W.

Suction ports 210 of the aforementioned film removing member 200 each have a slit shape in this example, and they are placed outside the plasma releasing part 201 and located facing to each other in the radial direction of the wafer W with the plasma releasing part 201 therebetween. The suction ports 201 are connected via a suction pipe 211 to a pump 212 installed outside.

The supply pipe 202 and the suction pipe 211 are provided with valves 203 and 213, respectively, and openings of these valves are controlled, for example, by a controlling unit 214, and by the control of the controlling unit 214, the flow rate of the gas plasma supplied from the plasma releasing part 201 and the suction flow rate from the suction ports 210 can be adjusted.

Even if the film removing member 200 structured as above is used, it is possible to remove the outer peripheral film R by the plasma and appropriately form the sloped part K similarly to the aforementioned film removing member 80. Moreover, in this film removing member 200, the opening which houses a peripheral edge part of the wafer W is unnecessary, and consequently the entire structure can be made more compact. Further, after being supplied and removing the film, the plasma is immediately sucked by the suction ports 210, whereby the plasma does not diffuse into the surroundings. The structure in which the gas plasma from the plasma releasing part 201 thus structured, that is, the plasma generator is introduced into the film removing member through the supply pipe and released from the plasma releasing part having the shape of a release port is applicable to the plasma releasing part 84 of the film releasing member 80 described above.

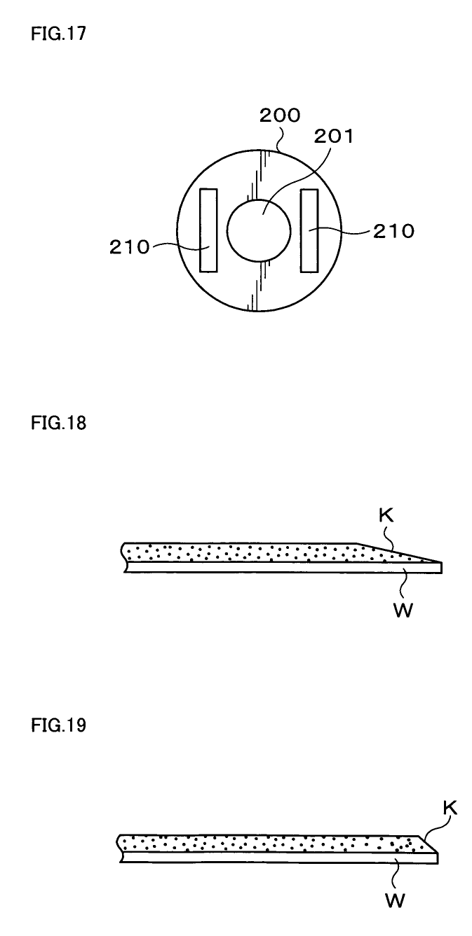

Furthermore, by changing the ratio between the supply amount and the suction amount of the gas plasma by the opening control of the valves 203 and 213, the slope of the sloped part K can be changed, similarly to the aforementioned film removing member 80. If the supply amount of the gas plasma is increased, the slope of the sloped part K becomes gentler as shown in FIG. 18, and if the suction amount is increased, the slope of the sloped part K becomes steeper as shown in FIG. 19.

As shown in FIG. 16, an oxygen radical supply part 220 for supplying oxygen radicals to the wafer W may be provided on the side of a rear surface of the wafer W. This oxygen radical supply part 220 has a function of supplying oxygen radicals generated by an oxygen radical generator 221 to the rear surface of the wafer W via a supply pipe 222. By the aforementioned supply of the oxygen radicals to the rear surface of the wafer W, for example, a region from the rear surface of the wafer W to an edge portion, and its strong oxidative effect, the unnecessary film and organic matters which have got into the rear surface side and become the cause of particles can be effectively removed. Incidentally, the supply amount of the oxidation radicals can be adjusted by the opening control of a valve 223, and this adjustment may be also controlled by the controlling unit 214. The oxygen radicals can be generated, for example, by the plasma, and hence, the plasma generator can be used as the oxygen radical generator 221.

The aforementioned oxygen radical supply part 220 may be, of course, placed on the upper surface side of the wafer W, used for the oxidizing processing after the film is removed, and moreover used together with the already mentioned various kinds of film removing members 110, 120, 130, and 140. When the oxygen radicals are supplied to the upper surface side of the wafer W, for example, by placing the oxygen radical supply part 220 on the upper surface side of the wafer W, it is also possible to generate oxygen radicals by the plasma generator 202 and supply the oxygen radicals as they are to the wafer W from the plasma releasing part 201 of the film removing member 200. Thereby, processing for improving the adhesion to the later formed insulating film can be performed without a break. Moreover, it is unnecessary to provide the oxygen radical generator additionally.

Incidentally, the removal and peeling of the outer peripheral film R and the removal of the organic matters which are already described may be performed while the wafer W is heated. For example, it can be proposed to heat the temperature of the wafer W to 60-100° C., for example, 80° C. Moreover, the supplied various kinds of gases may be heated and then supplied. In this case, it can be proposed to heat the temperature of each gas to 200-400° C., for example, approximately 300° C.

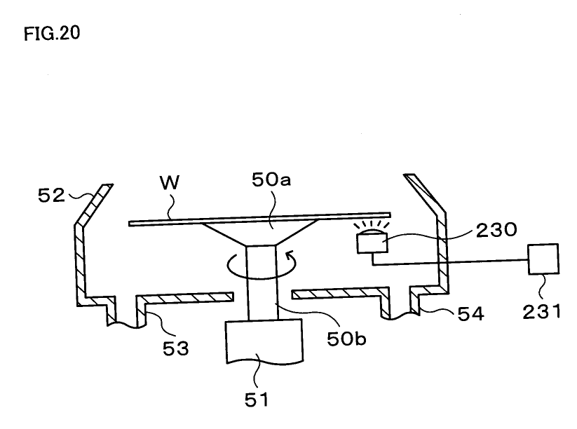

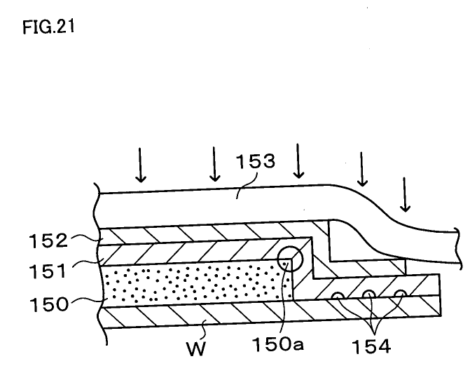

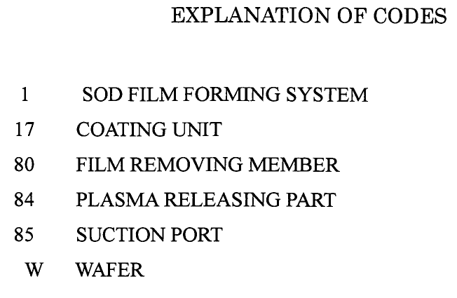

When the wafer W is heated, for example, as shown in FIG. 20, it can be proposed to radiate the lower surface of the wafer W by an infrared lamp 230. When a structure in which the wafer W is rotated is provided, the infrared ramp 230 has only to be provided at only one position. Because of heating by an infrared ray, heating without touching the wafer W is possible. The wafer W can be heated to any given temperature by control by a power supply 231.

In the aforementioned embodiment, the present invention is applied to the coating unit 17 for forming the interlayer insulating film, but the present invention is also applicable to a processing apparatus for forming a different kind of film, for example, an SOG film which is an insulating film, a polyimide film which is a protective film, a resist film, or the like. Moreover, the present invention is also applicable to a processing apparatus for substrates other than the wafer W such as an LCD substrate, a mask substrate, and a reticle substrate.

According to the present invention, an upper film does not peel off in polishing processing and the like, whereby the occurrence of particles and a product deficiency of a substrate can be prevented.

### INDUSTRIAL APPLICABILITY

The present invention is available when a process involving polishing processing as post-processing exists in manufacturing processes of a semiconductor device, an LCD substrate, or the like.

1. A processing apparatus for processing a substrate on a surface of which a film is formed, comprising:
a film removing member for selectively removing the film on a predetermined portion of an outer peripheral part of the substrate; and
a rotating mechanism for rotating the substrate,
said film removing member having a shape which is composed of a vertical part, an upper part formed in a horizontal direction from an upper end part of the vertical part, and a lower part formed in a same direction as the horizontal direction from a lower end part of the vertical part, being formed so that the outer peripheral part of the substrate is allowed to be inserted into an opening which is formed by the upper part and the lower part, and including a plasma supply part for supplying plasma of a reactive gas to the film on the predetermined portion and a suction port for sucking an atmosphere in a vicinity of the predetermined portion from outside the substrate, and
said plasma supply part being attached to a ceiling surface inside said film removing member surrounded by the vertical part, the upper part, and the lower part.

2. (canceled)

3. (canceled)

4. The processing apparatus as set forth in claim 1, wherein
said suction port is provided inside said film removing member and at a position facing the opening.

5. The processing apparatus as set forth in claim 1, wherein
said plasma supply part is provided in a portion facing the predetermined portion in said film removing member, and said suction port is provided outside said plasma supply part.

6. The processing apparatus as set forth in claim 5, wherein
said plasma supply part is provided in a portion facing the predetermined portion in said film removing member, and said suction ports are provided facing to each other with said plasma supply part therebetween.

7. (canceled)

8. The processing apparatus as set forth in claim 1, further comprising:
a horizontal driving part for horizontally moving said film removing member.

9. The processing apparatus as set forth in claim 1, further comprising:
a controlling part for controlling a suction pressure of said suction port.

10. The processing apparatus as set forth in claim 1, wherein
said plasma supply parts are provided at plural positions along a radial direction of the substrate in said film removing member.

11. The processing apparatus as set forth in claim 1, wherein
said plasma supply parts are provided at plural positions along a circumferential direction of the substrate in said film removing member.

12. The processing apparatus as set forth in claim 1, wherein
said plasma supply part is an emitting part of a ray for converting the reactive gas into the plasma.

13. The processing apparatus as set forth in claim 10, wherein
said film removing member further includes a reactive gas jetting part for jetting the reactive gas.

14. (canceled)

15. (canceled)

16. (canceled)

17. The processing apparatus as set forth in claim 1, further comprising:
a removal solution discharge nozzle for discharging a removal solution to the outer peripheral part of the substrate to remove the film on the outer peripheral part, in addition to said film removing member.

18. The processing apparatus as set forth in claim 1, further comprising:
a coating solution discharge nozzle for discharging a coating solution to the substrate to form the film on the substrate.

19. The processing apparatus as set forth in claim 1, further comprising:
an oxygen radical supply part for supplying oxygen radicals toward at least an outer peripheral part of a surface, which is different from the surface on which the film is formed, of the substrate.

20. The processing apparatus as set forth in claim 1, further comprising:
a heating unit for heating the substrate by an infrared ray.

21. A processing method for processing a substrate on a surface of which a film is formed, comprising the step of:
forming in the film on an outer peripheral part of the substrate a sloped part such that its film thickness becomes thinner toward an end part.

22. The processing method as set forth in claim 21, further comprising the steps of:
selectively removing the film on a portion of the outer peripheral part of the substrate; and
forming the sloped part such that its film thickness becomes thinner toward the portion from which the film is removed.

23. The processing method as set forth in claim 21, further comprising the step of:
oxidizing a surface of the sloped part.

24. The processing method as set forth in claim 23, wherein
the oxidation is performed by supplying oxygen radicals.
